(19) United States
(12) Patent Application Publication
(10) Pub. No.: US 2018/0174929 A1
(43) Pub. Date: Jun. 21, 2018

(54) SEMICONDUCTOR MANUFACTURING DEVICE, SEMICONDUCTOR MANUFACTURING METHOD AND SEMICONDUCTOR DEVICE

(71) Applicant: Renesas Electronics Corporation, Tokyo (JP)

(72) Inventor: Makoto TAMANOI, Tokyo (JP)

(21) Appl. No.: 15/805,191

(22) Filed: Nov. 7, 2017

(30) Foreign Application Priority Data
Dec. 19, 2016 (JP) 2016-245188

(51) Int. Cl. H01L 21/66; H01L 21/78; H01L 21/48; H01L 21/56; H01L 23/34; H01L 23/544; H01L 23/00; G01R 31/28; G01K 13/00

(52) U.S. Cl. CPC H01L 22/14; H01L 2924/141; H01L 21/78; H01L 21/4853; H01L 21/565; H01L 23/34; H01L 23/544; H01L 24/48; G01R 31/2877; G01K 13/00; H01L 2223/5446; H01L 2224/48227; H01L 2924/14511; H01L 2924/1437; H01L 2924/1432; H01L 22/32

(57) ABSTRACT

According to one embodiment, provided is a semiconductor manufacturing device including a probe card arranged to face a semiconductor chip to be measured, wherein the probe card has: a test probe that obtains the electric characteristics of the semiconductor chip by being brought into contact with a test pad; a temperature extraction probe that extracts temperature information of the semiconductor chip by being brought into contact with a temperature extraction pad that is coupled to a temperature sensor; a contact member that is brought into contact with the upper surface of the semiconductor chip to absorb the heat of the semiconductor chip; a driving unit that moves the contact member so as to allow the contact member to be brought into contact with or to be separated from the upper surface; and a control unit that controls the driving of the driving unit on the basis of the temperature information.

### CROSS-REFERENCE TO RELATED APPLICATIONS

The disclosure of Japanese Patent Application No. 2016-245188 filed on Dec. 19, 2016 including the specification, drawings and abstract is incorporated herein by reference in its entirety.

### BACKGROUND

The present invention relates to a semiconductor manufacturing device, a semiconductor manufacturing method, and a semiconductor device, and for example, a semiconductor manufacturing device, a semiconductor manufacturing method, and a semiconductor device in which the temperature of a semiconductor chip is adjusted in an inspection process of the semiconductor chip in a wafer state.

In an inspection process of a semiconductor chip, the temperature of the semiconductor chip becomes higher than the set temperature, and the inspection accuracy of the semiconductor chip is deteriorated in some cases due to heat generated from an electronic circuit operated at a high frequency (for example, 200 MHz or higher).

In each of Japanese Patent Nos. 3515904 and 3611174, a wafer burn-in apparatus provided with a temperature adjustment plate is described. In the wafer burn-in apparatus of each of Japanese Patent Nos. 3515904 and 3611174, in the case where the temperature of a wafer measured by a temperature sensor of the temperature adjustment plate is lower than the set temperature, a heater of the temperature adjustment plate is operated. Further, in the case where the temperature is higher than the set temperature, air whose temperature is set lower than the burn-in test temperature is blown. As described above, in the wafer burn-in apparatus of each of Japanese Patent Nos. 3515904 and 3611174, the temperature is adjusted by the heater and air blow.

In Japanese Patent No. 2556245, a probe card that cools a probe and a substrate by air is described. In the probe card of Japanese Patent No. 2556245, an air-blowing pipe for blowing air from the outside of the probe card is provided near probes that are densely coupled to the center portion of the probe card. Further, heat generated by the probes is radiated to suppress the temperature rise of the probes by forcibly blowing air onto the probes.

In Japanese Patent No. 4894582, a probe card having a probe for performing an electric characteristic test of a semiconductor chip and a temperature sensor probe for detecting the temperature of a wafer is described. In Japanese Patent No. 4894582, the temperature sensor probe is brought into contact with a dicing portion of the wafer, and the electric characteristic test of the semiconductor chip is performed while detecting the temperature of the chip.

In Japanese Unexamined Patent Application Publication No. Hei 11 (1999)-126807, a burn-in apparatus that uses a diode element formed of a PN junction formed on a wafer as a temperature detection element of the wafer is described. In the burn-in apparatus of Japanese Unexamined Patent Application Publication No. Hei 11 (1999)-126807, the detection of the temperature of the wafer and the inspection of an integrated circuit are carried out by using a probe card closely adhering to the wafer.

### SUMMARY

In each of Japanese Patent Nos. 3515904, 3611174, and 2556245, a cooling method such as blowing cooling air is adopted as a measure against the heat generated at the time of the inspection of the semiconductor chip. In such a cooling method, there is a possibility that the air does not reach all the semiconductor chips to be measured, and it is not possible to sufficiently cool the semiconductor chip which the air does not reach.

As another measure against the heat generated at the time of the inspection of the semiconductor chip, there is a method in which, for example, semiconductor chips to be inspected and not to be inspected that are arrayed on a wafer are alternately placed, and the heat is absorbed by the semiconductor chips not to be inspected between those to be inspected. In this method, however, it takes twice the time due to the inspection of the semiconductor chips not to be inspected, resulting in an increase in cost.

An embodiment has been made to solve such a problem, and an object of the present invention is to provide a semiconductor manufacturing device, a semiconductor manufacturing method, and a semiconductor device capable of accurately controlling the temperature of a semiconductor chip to be inspected.

The other objects and novel features will become apparent from the description of the specification and the accompanying drawings.

According to one embodiment, provided is a semiconductor manufacturing device including a probe card arranged to face a semiconductor chip to be measured, wherein the probe card has: a test probe that inspects the semiconductor chip by being brought into contact with a test pad provided over the upper surface of the semiconductor chip; a temperature extraction probe that obtains temperature information of the semiconductor chip by being brought into contact with a temperature extraction pad that is coupled to a temperature sensor provided in the semiconductor chip and is provided over the upper surface; a contact member that is brought into contact with the upper surface of the semiconductor chip to absorb the heat of the semiconductor chip; a driving unit that moves the contact member so as to allow the contact member to be brought into contact with or to be separated from the upper surface; and a control unit that controls the driving of the driving unit on the basis of the temperature information.

According to the embodiment, a semiconductor manufacturing device, a semiconductor manufacturing method, and a semiconductor device capable of accurately controlling the temperature of a semiconductor chip to be inspected are provided.

### BRIEF DESCRIPTION OF THE DRAWINGS

FIG. 1 is a cross-sectional view for exemplifying a semiconductor manufacturing device according to a first embodiment;

FIG. 2 is a perspective view for exemplifying a semiconductor chip, a probe unit of a probe card, a contact member, and a heat transfer member in the semiconductor manufacturing device according to the first embodiment;

FIG. 3 is a cross-sectional view for exemplifying the contact member separated from the semiconductor chip in the semiconductor manufacturing device according to the first embodiment;

FIG. 4 is a flowchart for exemplifying a semiconductor manufacturing method according to the first embodiment;

FIG. 5 is a plan view for exemplifying the semiconductor chips in a wafer state in the semiconductor manufacturing method according to the first embodiment;

FIGS. 6A to 6C are diagrams each exemplifying another example of a temperature sensor of the semiconductor chip in the semiconductor manufacturing method according to the first embodiment;

FIGS. 7A and 7B are diagrams each exemplifying another example of the temperature sensor of the semiconductor chips in the wafer state in the semiconductor manufacturing method according to the first embodiment;

FIG. 8 is a cross-sectional view for exemplifying a structure of the temperature sensor of the semiconductor chip according to the first embodiment;

FIG. 9 is a graph for exemplifying a relation between the temperatures and electric resistances of a semiconductor and metal;

FIG. 10 is a flowchart for exemplifying a wafer inspecting process in the semiconductor manufacturing method according to the first embodiment;

FIG. 11 is a block diagram for exemplifying a method of controlling the temperature of the semiconductor chip according to the first embodiment;

FIG. 12A is a plan view for exemplifying pads after the wafer inspecting process in the semiconductor manufacturing method according to the first embodiment, and FIG. 12B is a plan view for exemplifying the upper surface of the semiconductor chip after the wafer inspecting process;

FIG. 13 is a plan view for exemplifying the packaged semiconductor chip in the semiconductor manufacturing method according to the first embodiment;

FIG. 14 is a plan view for exemplifying the packaged semiconductor chip in the semiconductor manufacturing method according to the first embodiment;

FIG. 15 is a cross-sectional view for exemplifying a structure of a temperature sensor according to a first modified example of the first embodiment;

FIG. 16 is a cross-sectional view for exemplifying a structure of a temperature sensor according to a second modified example of the first embodiment;

FIG. 17 is a cross-sectional view for exemplifying a structure of a temperature sensor according to a third modified example of the first embodiment;

FIG. 18 is a cross-sectional view for exemplifying a configuration of a semiconductor manufacturing device according to a second embodiment; and

FIG. 19 is a block diagram for exemplifying a method of controlling the temperature of a semiconductor chip using a bimetal according to the second embodiment.

### DETAILED DESCRIPTION

For the sake of clarifying the explanation, the following description and drawings are appropriately omitted and simplified. In addition, in the case where the drawings become complicated or a boundary with an air gap is distinguishable in the drawings, hatching or the like is omitted in some cases even in a cross section. It should be noted that the same elements are followed by the same reference numerals in each drawing, and duplicated explanation is omitted as necessary.

### First Embodiment

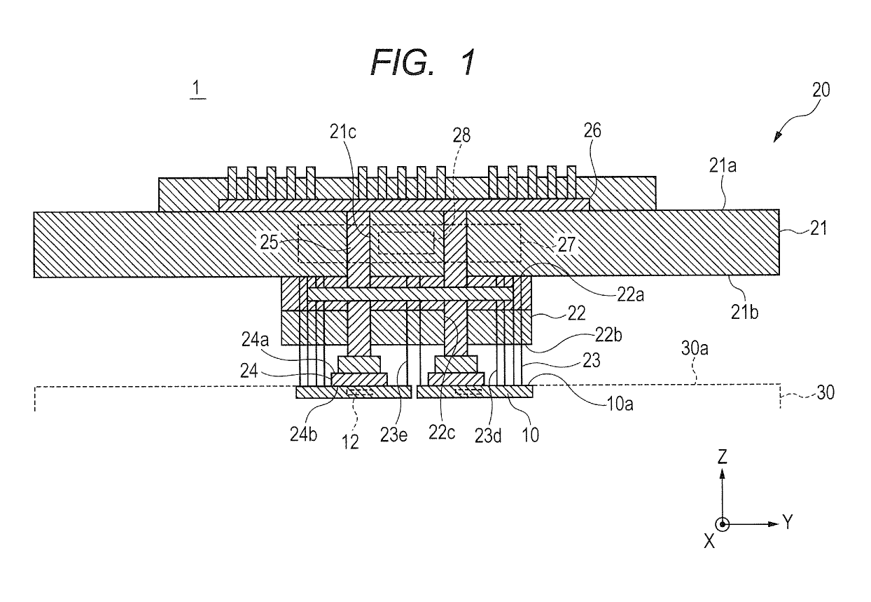

First, an outline of a semiconductor manufacturing device according to a first embodiment will be described. FIG. 1 is a cross-sectional view for exemplifying a semiconductor manufacturing device according to the first embodiment. As shown in FIG. 1, a semiconductor manufacturing device 1 according to the first embodiment includes a probe card 20 for inspecting a semiconductor chip 10.

The probe card 20 is a jig for inspecting electric characteristics of the semiconductor chip 10. The probe card 20 is arranged to face the semiconductor chip 10 to be measured. The probe card 20 is arranged so as to face a wafer surface 30a of a wafer 30 on which a plurality of semiconductor chips 10 is formed.

The probe card 20 has a main substrate 21, a relay substrate 22, a probe unit 23, a contact member 24, a heat transfer member 25, a heat radiation member 26, a driving unit 27, and a control unit 28. The semiconductor chip 10 to be inspected is in the wafer state before dicing.

The main substrate 21 is, for example, a plate-like member. The main substrate 21 is arranged to face the wafer 30 so as to cover the wafer surface 30a. Here, in order to explain the semiconductor manufacturing device 1, an XYZ orthogonal coordinate system is introduced. When the semiconductor chip 10 to be inspected is arranged, the direction connecting the semiconductor chip 10 to the probe card 20 is assumed as the Z-axis direction, and the direction from the semiconductor chip 10 to the probe card 20 is assumed as the +Z-axis direction. The +Z-axis direction is, for example, an upward direction. One direction orthogonal to the Z-axis direction is assumed as the Y-axis direction, and the direction orthogonal to the Y-axis direction and the Z-axis direction is assumed as the X-axis direction. It should be noted that the XYZ orthogonal coordinate system is introduced to explain the configuration of the semiconductor manufacturing device 1. When the semiconductor manufacturing device 1 is used, the direction from the semiconductor chip 10 to the main substrate 21 may be a direction other than the upward direction as long as the main substrate 21 is arranged to face the wafer 30.

The main substrate 21 is a member in which internal wirings, external wirings, and the like are provided on an insulating substrate. The main substrate 21 is coupled to a tester main body (not shown) via a wiring (not shown). The lower surface 21b of the main substrate 21 faces the upper surface 10a of the semiconductor chip 10. The relay substrate 22 is attached to the lower surface 21b of the main substrate 21. The heat radiation member 26 is attached to the upper surface 21a of the main substrate 21. The main substrate 21 is provided with a through-hole 21c penetrating from the upper surface 21a to the lower surface 21b. A plurality of through-holes 21c may be provided. The heat transfer member 25 is inserted into the through-hole 21c from the lower surface 21b side. The heat transfer member 25 inserted into the through-hole 21c is coupled to the heat radiation member 26 attached to the upper surface 21a of the main substrate 21.

The relay substrate 22 is, for example, a plate-like member, and has an upper surface 22a and a lower surface 22b. The upper surface 22a of the relay substrate 22 faces the lower surface 21b of the main substrate 21, and is in contact with, for example, the lower surface 21b of the main substrate 21. The relay substrate 22 is a member in which internal wirings, external wirings, and the like are provided on an insulating substrate. The lower surface 22b of the relay substrate 22 faces the upper surface 10a of the semiconductor chip 10.

The relay substrate 22 is provided with a through-hole 22c penetrating from the upper surface 22a to the lower surface 22b. A plurality of through-holes 22c may be provided. The through-hole 22c communicates with the through-hole 21c of the main substrate 21. The heat transfer member 25 is inserted into the through-hole 22c. The heat transfer member 25 coupled to the heat radiation member 26 at the upper surface 21a of the main substrate 21 protrudes downward from the lower surface 22b of the relay substrate 22 through the through-hole 21c and the through-hole 22c. The probe unit 23 extends downward, namely, to the semiconductor chip 10 side from the lower surface 22b of the relay substrate 22.

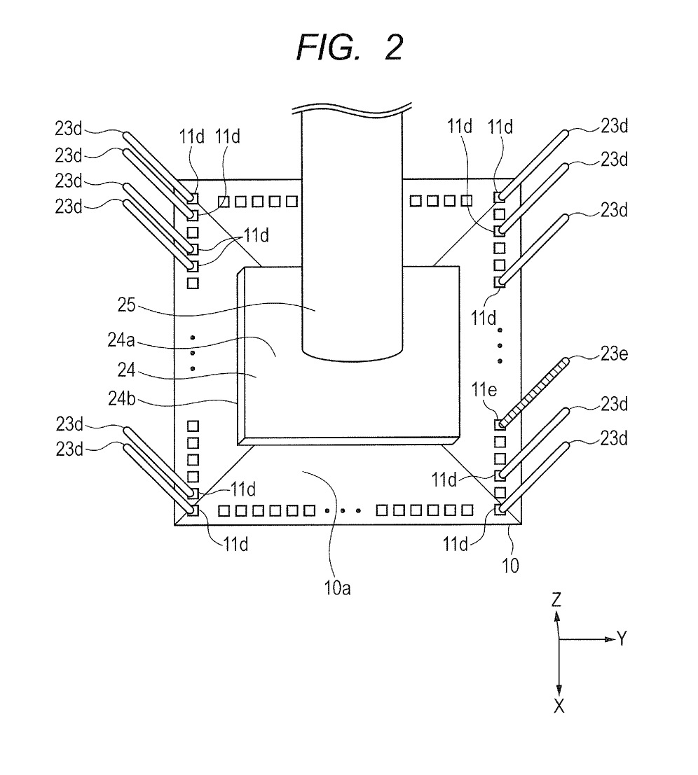

FIG. 2 is a perspective view for exemplifying the semiconductor chip 10, the probe unit 23 of the probe card 20, the contact member 24, and the heat transfer member 25 in the semiconductor manufacturing device 1 according to the first embodiment. As shown in FIG. 1 and FIG. 2, the probe unit 23 includes test probes 23d and a temperature extraction probe 23e. The test probes 23d and the temperature extraction probe 23e are collectively referred to as probes 23d and 23e.

The upper end portions of the probes 23d and 23e are fixed to the relay substrate 22. Each of the probes 23d and 23e is coupled to a predetermined wiring of the main substrate 21 via the relay substrate 22 or directly. Each of the probes 23d and 23e may extend in one direction or may have a curved portion. Each of the probes 23d and 23e is a thin needle-like conductive member. Each of the probes 23d and 23e contains a palladium alloy or tungsten as a material. It should be noted that each of the probes 23d and 23e may contain a material other than a palladium alloy or tungsten. The lower end of each of the probes 23d and 23e faces downward.

As shown in FIG. 2, for example, the test probes 23d are provided for each semiconductor chip 10. The test probes 23d are in contact with test pads 11d provided at the peripheral portion of the upper surface 10a of the semiconductor chip 10. Accordingly, the test probes 23d can obtain electric characteristics of the semiconductor chip 10. In the case where the semiconductor chips 10 to be inspected are formed on the wafer surface 30a of the wafer 30, each test probe 23d obtains electric characteristics of each semiconductor chip 10. For example, the semiconductor chips 10 formed on the wafer 30 are simultaneously inspected. Information including the electric characteristics obtained from the test probes 23d is processed by a tester main body (not shown) via the main substrate 21.

One temperature extraction probe 23e is provided for each semiconductor chip 10. It should be noted that a plurality of temperature extraction probes 23e may be provided for each semiconductor chip 10. The temperature extraction probe 23e is in contact with a temperature extraction pad 11e provided at the peripheral portion of the upper surface 10a of the semiconductor chip 10. Accordingly, the temperature extraction probe 23e extracts temperature information of the semiconductor chip 10.

As shown in FIG. 1, a temperature sensor 12 is provided in the semiconductor chip 10. The temperature extraction pad 11e is coupled to the temperature sensor 12. The temperature information is transmitted from the temperature extraction probe 23e to the control unit 28.

The contact member 24 is coupled to the lower end of the heat transfer member 25 protruding downward from the lower surface 22b of the relay substrate 22. The contact member 24 is, for example, a sheet-like member, and the upper surface 24a thereof is coupled to the lower end of the heat transfer member 25. It should be noted that only two semiconductor chips 10 and two contact members 24 are shown in FIG. 1, and only one semiconductor chip 10 and one contact member 24 are shown in FIG. 2. However, a number of semiconductor chips 10 are actually formed on the wafer surface 30a of the wafer 30. In addition, a number of contact members 24 are formed in accordance with the number of the semiconductor chips 10.

The contact member 24 contains an insulating material having high heat conductivity as a material. For example, the contact member 24 contains a material used for a general heat radiation sheet. It should be noted that the material of the contact member 24 is not limited to the material used for a general heat radiation sheet. The contact member 24 is brought into contact with the upper surface 10a of the semiconductor chip 10, and absorbs the heat of the semiconductor chip 10. The contact member 24 is brought into contact with, for example, a central portion of the upper surface 10a of the semiconductor chip 10. The lower surface 24b of the contact member 24 is structured so as not to damage the semiconductor chip 10 when the lower surface 24b of the contact member 24 is brought into contact with the upper surface 10a of the semiconductor chip 10. For example, the lower surface 24b of the contact member 24 has a flexible structure such as a heat radiation sheet. When the lower surface 24b of the contact member 24 is brought into contact with the upper surface 10a of the semiconductor chip 10, the heat of the semiconductor chip 10 is thermally conducted to the contact member 24.

The heat transfer member 25 is, for example, a rod-like member, and contains a material having high heat conductivity. The heat transfer member 25 is, for example, a metal member. The heat transfer member 25 is inserted into the through-hole 21c provided in the main substrate 21 and the through-hole 22c provided in the relay substrate 22. The upper end of the heat transfer member 25 inserted into the through-hole 21c and the through-hole 22c is coupled to the heat radiation member 26 attached to the upper surface 21a of the main substrate 21. The lower end of the heat transfer member 25 protrudes downward from the lower surface 22b of the relay substrate 22, and is coupled to the upper surface 24a of the contact member 24. As described above, the heat transfer member 25 couples the contact member 24 and the heat radiation member 26 to each other, and moves the heat absorbed by the contact member 24 to the heat radiation member 26.

The driving unit 27 is attached to the heat transfer member 25. The heat transfer member 25 expands and contracts in the vertical direction by driving the driving unit 27. For example, the heat transfer member 25 has a spring mechanism between the upper end and the lower end, and expands and contracts in the vertical direction by driving the driving unit 27. Alternatively, the heat transfer member 25 has, for example, a tubular part at a part between the upper end and the lower end, and slides in the vertical direction by driving the driving unit 27 to expand and contract. The upper end side of the heat transfer member 25 is fixed to the heat radiation member 26. Therefore, when the heat transfer member 25 expands and contracts in the vertical direction, the lower end moves upward or downward.

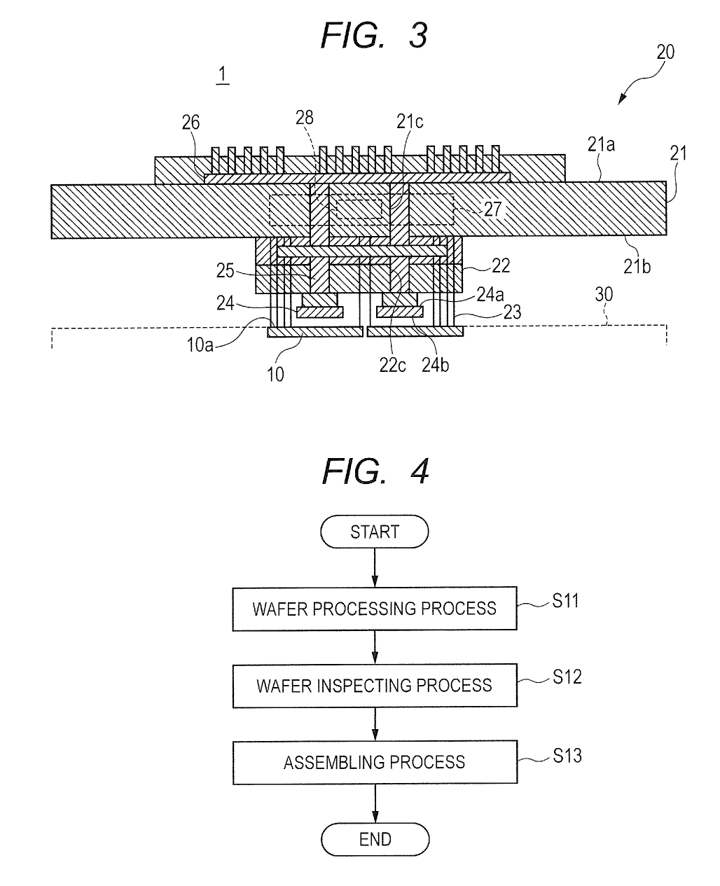

FIG. 3 is a cross-sectional view for exemplifying the contact member 24 separated from the semiconductor chip 10 in the semiconductor manufacturing device 1 according to the first embodiment. As shown in FIG. 3, when the heat transfer member 25 contracts in the vertical direction, the lower end moves upward. In accordance with such movement of the lower end of the heat transfer member 25, the contact member 24 is separated from the upper surface 10a of the semiconductor chip 10. On the other hand, when the heat transfer member 25 expands in the vertical direction, the lower end moves downward. In accordance with such movement of the lower end of the heat transfer member 25, the contact member 24 is brought into contact with the upper surface 10a of the semiconductor chip 10 as shown in FIG. 1 and FIG. 2. It should be noted that the heat transfer member 25 is not limited to expanding and contracting to move the contact member 24. Other operation methods may be employed as long as the heat transfer member 25 can allow the contact member 24 to be brought into contact with or to be separated from the semiconductor chip 10.

The heat radiation member 26 is attached to the upper surface 21a of the main substrate 21. Therefore, the heat radiation member 26 is provided on the side opposite to the side where the semiconductor chip 10 is arranged. The heat radiation member 26 is a heat sink containing a member having high heat conductivity as a material. The heat radiation member 26 is, for example, a metal member. The upper end of the heat transfer member 25 inserted into the through-holes 21c and 22c of the main substrate 21 and the relay substrate 22 is coupled to the heat radiation member 26. Accordingly, the heat absorbed by the contact member 24 is received via the heat transfer member 25. Then, the heat radiation member 26 radiates the heat received from the heat transfer member 25 to the outside.

For example, the heat radiation member 26 may be provided with a plurality of fins protruding upward. Further, a fan for air-cooling the heat radiation member 26 may be provided in the vicinity of the heat radiation member 26. The heat radiation efficiency of the heat radiation member 26 can be improved by providing the fins and the fan. In order to add strength to the heat radiation member 26, a reinforcing member may be attached.

The driving unit 27 is attached to the main substrate 21. The driving unit 27 moves the lower end of the heat transfer member 25 in the vertical direction. Accordingly, the driving unit 27 moves the contact member 24 so as to allow the contact member 24 to be brought into contact with or to be separated from the upper surface 10a of the semiconductor chip 10. At this time, the driving unit 27 moves the contact member 24 via the heat transfer member 25. The driving unit 27 is, for example, a motor.

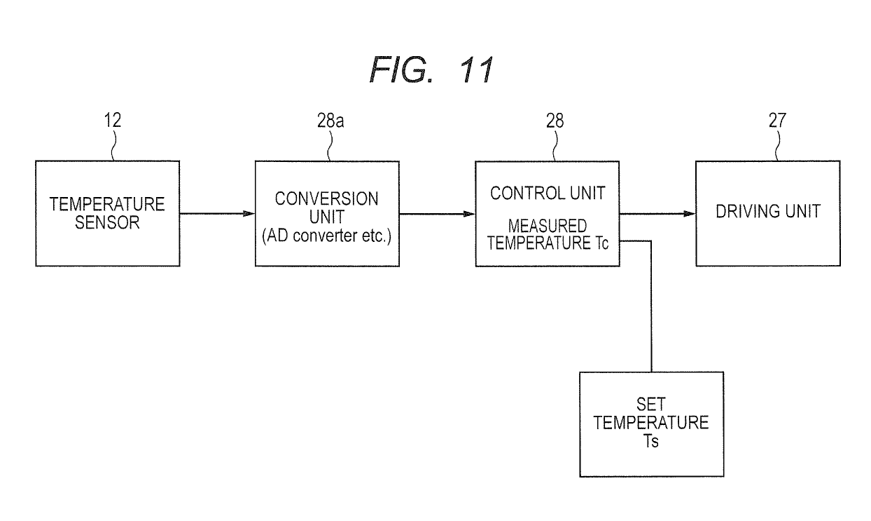

The control unit 28 is attached to, for example, the main substrate 21. The control unit 28 includes, for example, electronic parts such as a CPU, a memory, and a microcomputer. In addition, a conversion unit 28a (AD converter and the like) (see FIG. 11) for converting into a signal format that can be used by the control unit 28 may be attached to the control unit 28. The control unit 28 is coupled to the temperature extraction probe 23e by information transmission means such as a signal line. Further, the control unit 28 is coupled to the driving unit 27 by information transmission means such as a signal line. The control unit 28 stores the set temperature at the time of inspecting the semiconductor chip 10. The control unit 28 compares the temperature information obtained from the temperature extraction probe 23e with the set temperature, and controls the driving unit 27 so as to keep the set temperature. Accordingly, the driving unit 27 operates the heat transfer member 25 so that the contact member 24 is brought into contact with or is separated from the semiconductor chip 10. In this way, the control unit 28 feedback-controls the driving of the driving unit 27 on the basis of the temperature information obtained from the temperature extraction probe 23e.

Next, a semiconductor manufacturing method according to the first embodiment will be described. The semiconductor manufacturing method is a method of manufacturing a semiconductor device having the semiconductor chip 10 using the semiconductor manufacturing device 1.

FIG. 4 is a flowchart for exemplifying the semiconductor manufacturing method according to the first embodiment. First, as shown in Step S11 of FIG. 4, a wafer processing process is performed. In the wafer processing process, for example, each process such as a film formation process, a photoresist process, and an ion implantation process is performed on the wafer 30 made of silicon as a material to form the semiconductor chips 10 on the wafer 30. It should be noted that the material of the wafer 30 is not limited to silicon.

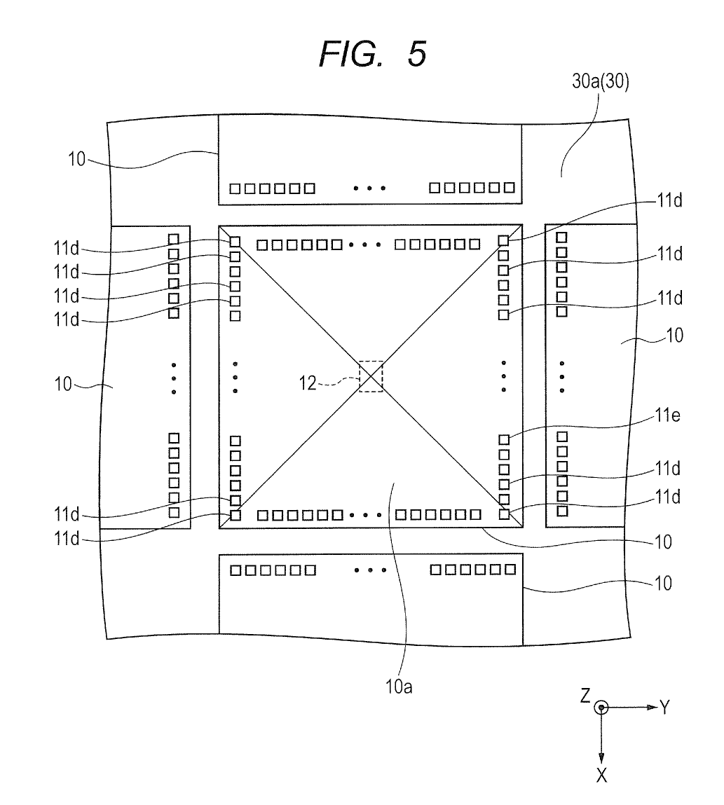

FIG. 5 is a plan view for exemplifying the semiconductor chips 10 in the wafer state in the semiconductor manufacturing method according to the first embodiment. As shown in FIG. 5, the semiconductor chips 10 are formed on the wafer surface 30a of the wafer 30 by performing the wafer processing process. The semiconductor chips 10 are in the wafer state before dicing that is an inspection target for electric characteristics. The semiconductor chips 10 include the test pads 11d, the temperature extraction pads 11e, and the temperature sensors 12.

The test pads 11d and the temperature extraction pad 11e are formed on the upper surface 10a of each semiconductor chip 10. The test probes 23d for obtaining the electric characteristics of the semiconductor chip 10 are brought into contact with the test pads 11d. A plurality of test pads 11d is provided. For example, when the upper surface 10a of each semiconductor chip 10 is viewed from the upper direction, the test pads 11d are provided at the peripheral portions on the +Y-axis direction side and the −Y-axis direction side. The test pads 11d are coupled to an electronic circuit formed in the semiconductor chip 10 via a wiring formed in the semiconductor chip 10.

The temperature extraction probe 23e for extracting the temperature information is brought into contact with the temperature extraction pad 11e. Further, the temperature extraction pad 11e is coupled to the temperature sensor 12 via a wiring inside the semiconductor chip 10. The temperature sensor 12 outputs the temperature information of the semiconductor chip 10.

One temperature extraction pad 11e or a plurality of temperature extraction pads 11e may be provided. For example, the temperature extraction pad 11e is provided at the peripheral portion on the +Y-axis direction side of the upper surface 10a of each semiconductor chip 10.

The test pads 11d and the temperature extraction pads 11e are collectively referred to as pads 11d and 11e. Pads other than the pads 11d and 11e are also formed on the upper surface 10a of each semiconductor chip 10.

The upper surface 10a of each semiconductor chip 10 is in a rectangular shape. For example, the upper surface 10a is in a square shape. The pads 11d and 11e and pads (hereinafter, referred to as pads 11) other than the pads 11d and 11e are provided, for example, at the peripheral portions of the upper surface 10a of each semiconductor chip 10. In addition, the pads 11 contain aluminum as a material. It should be noted that the pads 11 may be formed using a material other than aluminum.

The contact member 24 that absorbs heat can be brought into contact with the upper surface 10a of each semiconductor chip 10. For example, the contact member 24 can be brought into contact with the central portion of the upper surface 10a.

For example, the temperature sensor 12 is formed in the central portion when viewed from the upper direction of each semiconductor chip 10. It should be noted that the position where the temperature sensor 12 is provided is not limited to the central portion of each semiconductor chip 10. For example, the temperature sensor 12 of a contact type is formed. The contact type has the meaning opposite to a non-contact type using infrared rays or the like. As the contact-type temperature sensors 12, there are electric-type temperature sensors and mechanical-type temperature sensors. As the electric-type temperature sensors, there are a resistance temperature detector (RTD), a thermistor, a thermocouple, an IC temperature sensor, and the like. As the mechanical-type temperature sensors, there are a temperature sensitive ferrite, a bimetal, and the like. In the embodiment, a contact-type electrical RTD or thermistor is used.

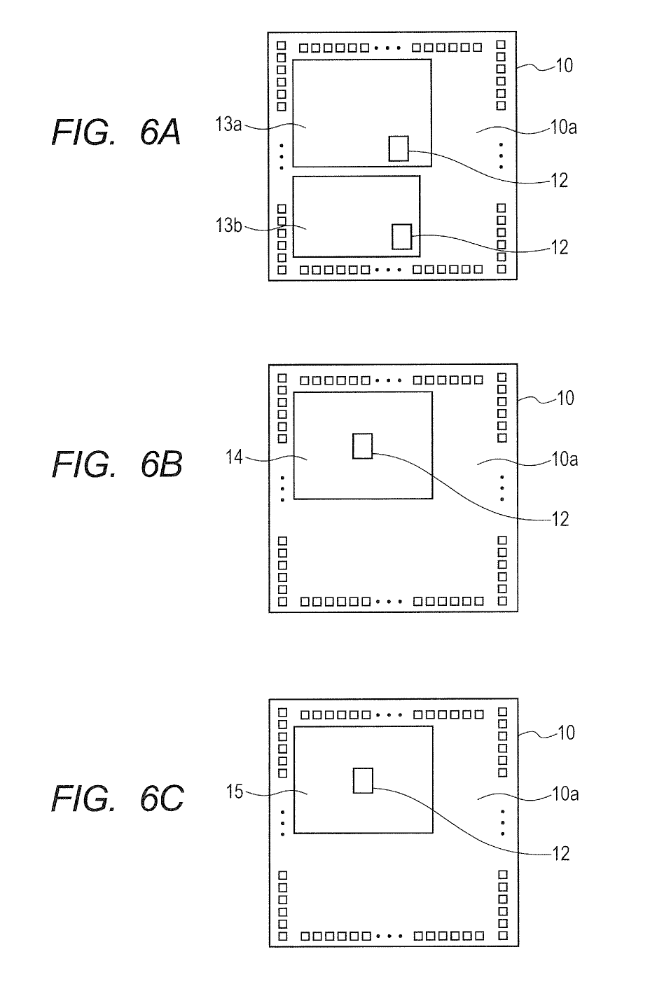

FIGS. 6A to 6C are diagrams each exemplifying another example of the temperature sensor 12 of the semiconductor chip 10 in the semiconductor manufacturing method according to the first embodiment. As shown in FIG. 6A, the temperature sensor 12 is provided in each of the formation regions of a flash memory 13a and an SRAM 13b (Static Random Access Memory) in the semiconductor chip 10. Further, a plurality of temperature sensors 12 may be provided in the semiconductor chip 10. The temperature distribution in the semiconductor chip 10 can be measured by providing the temperature sensors 12 at the central portion and the peripheral portion of the semiconductor chip 10.

As shown in FIG. 6B, the temperature sensor 12 may be provided in the formation region of a CPU (Central Processing Unit) 14 in the semiconductor chip 10. A high-frequency current flows in the CPU 14, and thus the temperature of the region becomes high. The temperature of the semiconductor chip 10 can be accurately measured by providing the temperature sensor 12 in such a high temperature region.

Further, as shown in FIG. 6C, the temperature sensor 12 may be provided in the formation region of an analog IP 15 that is the IP core of the analog circuit in the semiconductor chip 10. In this case, the analog IP 15 may be limited to an analog IP 15 with large heat generation. As described above, in the process of forming the semiconductor chip 10, the temperature sensor 12 may be formed in at least one of the flash memory 13a, the SRAM 13b, the CPU 14, and the analog IP 15 of the semiconductor chip 10.

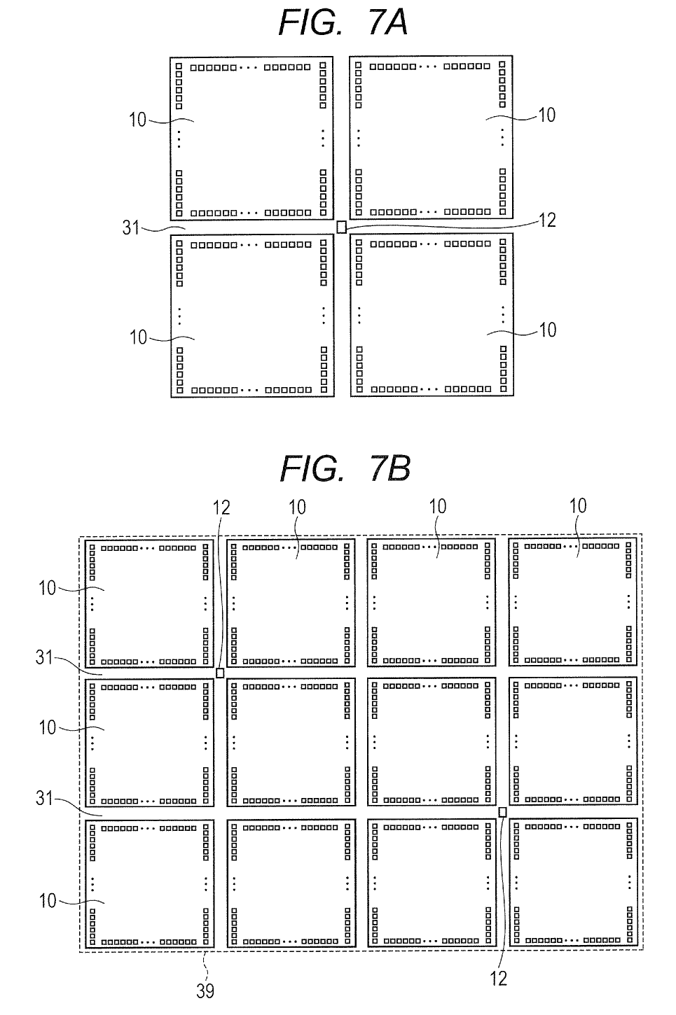

FIGS. 7A and 7B are diagrams each exemplifying another example of the temperature sensor 12 of the semiconductor chips 10 in the wafer state in the semiconductor manufacturing method according to the first embodiment. As shown in FIG. 7A, in the process of forming the semiconductor chip 10, the temperature sensor 12 may be formed in a scribe line 31 between the semiconductor chips 10 in the wafer state. Further, as shown in FIG. 7B, in the process of forming the semiconductor chip 10, the temperature sensors 12 may be formed for each region 39 formed in units of reticles.

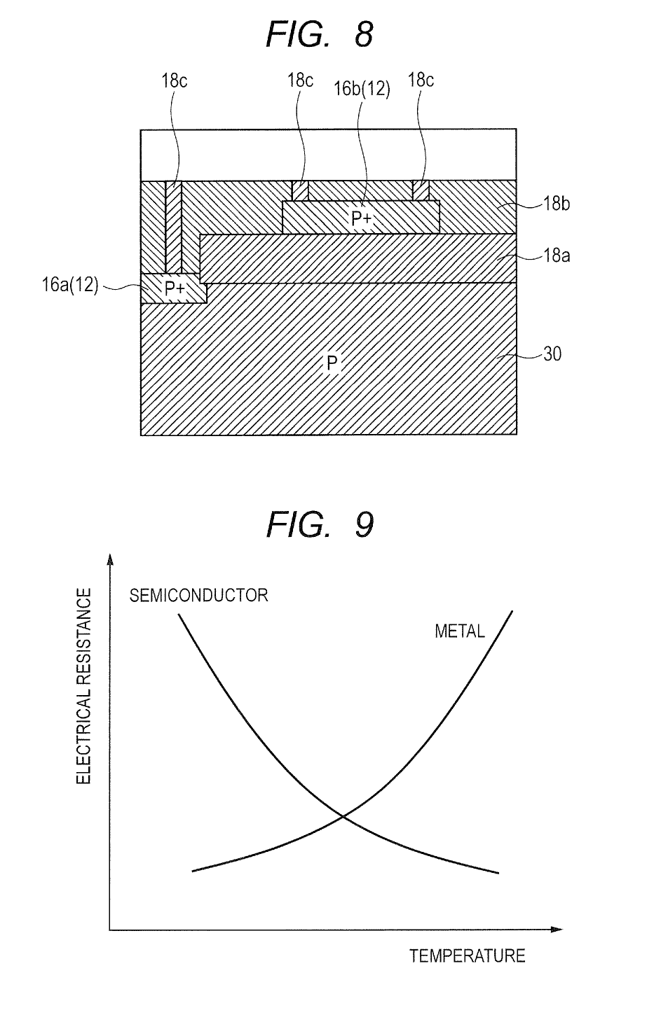

FIG. 8 is a cross-sectional view for exemplifying a structure of the temperature sensor 12 of the semiconductor chip 10 according to the first embodiment. As shown in FIG. 8, the temperature sensor 12 includes, for example, a resistor 16a or a resistor 16b. The temperature sensor 12 outputs changes in the current and voltage of the resistor 16a or the resistor 16b as temperature information. The resistor 16a is, for example, an impurity region formed by implanting high-concentration P-type impurities into the wafer 30 using an insulating film 18a as a mask. The resistor 16b is formed, for example, by forming a polysilicon film containing high-concentration P-type impurities on the insulating film 18. Wirings 18c are formed in an insulating film 18b formed so as to cover the resistor 16a and the resistor 16b, and are coupled to the temperature extraction pad 11e.

In the case where the resistor 16a is used as the temperature sensor 12, the temperature information is obtained on the basis of changes in the current and voltage between a ground terminal (not shown) of the wafer 30 and the temperature extraction pad 11e coupled to the resistor 16a. On the other hand, in the case where the resistor 16b is used as the temperature sensor 12, the temperature information is obtained on the basis of changes in the current and voltage between the two temperature extraction pads 11e coupled to both ends of the resistor 16b.

FIG. 9 is a graph for exemplifying a relation between the temperatures and electric resistances of a semiconductor and metal. As shown in FIG. 9, in the case where the temperature sensor 12 uses a semiconductor such as a silicon wafer or polysilicon as the resistor 16a and the resistor 16b, the electric resistance has a profile that decreases as the temperature rises. Therefore, the temperature information can be obtained from the temperature sensor 12 on the basis of changes in resistance as shown in FIG. 9. As described above, in the process of forming the semiconductor chip 10, the temperature sensor 12 includes a semiconductor such as a silicon wafer or polysilicon, and is formed so as to output the temperature information on the basis of the relation between the temperature and resistance in the semiconductor. It should be noted that although silicon or polysilicon doped with impurities is shown as the temperature sensor 12, the temperature sensor 12 is not limited to one using these elements.

As described above, in the wafer processing process, the semiconductor chips 10 are formed on the wafer 30. Then, each semiconductor chip 10 is formed so as to include the pads 11d and 11e, the temperature sensor 12, and, if necessary, the flash memory 13a, the SRAM 13b, the CPU 14 and the analog IP 15.

Next, as shown in Step S12 of FIG. 4, a wafer inspecting process is performed. Specifically, the electric characteristics of the semiconductor chip 10 in the wafer state are inspected using the probe card 20.

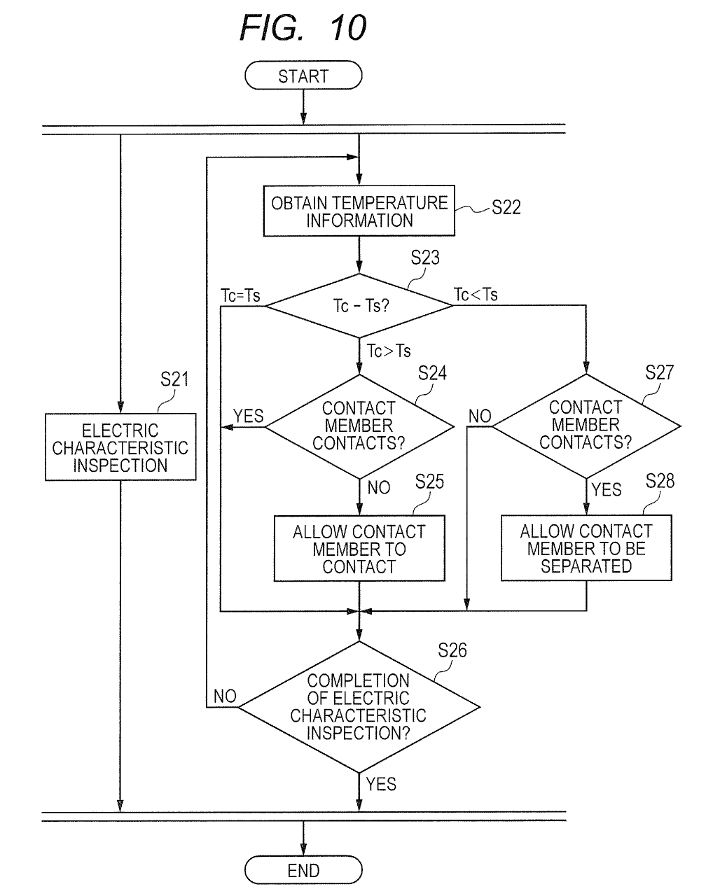

FIG. 10 is a flowchart for exemplifying the wafer inspecting process in the semiconductor manufacturing method according to the first embodiment. FIG. 11 is a block diagram for exemplifying a method of controlling the temperature of the semiconductor chip 10 according to the first embodiment.

As shown in Step S21 of FIG. 10 and FIG. 2, in the wafer inspecting process, the electric characteristics of the semiconductor chip 10 are inspected. Specifically, the test probes 23d are brought into contact with the test pads 11d provided on the upper surface 10a of the semiconductor chip 10 to be measured. For example, when the upper surface 10a of the semiconductor chip 10 is viewed from the upper direction, the test probes 23d are brought into contact with the test pads 11d provided at the peripheral portion of the upper surface 10a on the −Y-axis direction side. Similarly, the test probes 23d are brought into contact with the test pads 11d provided at the peripheral portion of the upper surface 10a on the +Y-axis direction side. Accordingly, the electric characteristics of the semiconductor chip 10 are obtained.

Further, as shown in Step S22 of FIG. 10, the temperature information of the semiconductor chip 10 is obtained. Specifically, the temperature extraction probe 23e is brought into contact with the temperature extraction pad 11e provided at the peripheral portion of the upper surface 10a on the +Y-axis direction side. The temperature extraction pad 11e is coupled to the temperature sensor 12 provided in the semiconductor chip 10. Accordingly, the control unit 28 obtains the temperature information of the semiconductor chip 10.

In the wafer inspecting process, in the case where the frequency of the internal operation of the semiconductor chip 10 is high, the heat generated from each semiconductor chip 10 is increased. Therefore, there is a case that the temperature deviates from the set temperature in the wafer inspecting process. In such a case, it is difficult to accurately measure the electric characteristics of the semiconductor chip 10.

Accordingly, as shown in FIG. 11, in the embodiment, the temperature information obtained from the temperature sensor 12 via the temperature extraction pad 11e is converted by the conversion unit 28a (AD converter and the like) into, for example, a signal format that can be used by the control unit 28 to be transmitted to the control unit 28. Then, the control unit 28 monitors the temperature of the semiconductor chip 10 on the basis of the received temperature information. The temperature thus obtained is referred to as a measured temperature Tc. The control unit 28 compares the measured temperature Tc with a set temperature Ts stored in a memory or the like. When the measured temperature Tc becomes higher than the set temperature Ts, the control unit 28 drives the driving unit 27 to allow the contact member 24 to be brought into contact with the upper surface 10a of the semiconductor chip 10. Accordingly, the semiconductor chip 10 is cooled.

Specifically, as shown in Step S23 of FIG. 10, the control unit 28 compares the measured temperature Tc of the semiconductor chip 10 with, for example, the set temperature Ts stored in a memory or the like. In the case where the measured temperature Tc is higher than the set temperature Ts (Tc>Ts), the control unit 28 determines whether the contact member 24 is in contact with the semiconductor chip 10 as shown in Step S24 of FIG. 10. In the case where the contact member 24 is not in contact with the semiconductor chip 10 (No), the contact member 24 is brought into contact with the upper surface 10a of the semiconductor chip 10 as shown in Step S25 of FIG. 10.

Thereafter, as shown in Step S26 of FIG. 10, it is determined whether the inspection of the electric characteristics in Step S21 has been completed. In the case where the inspection of the electric characteristics has been completed (Yes), the process is completed. On the other hand, in the case where the inspection of the electric characteristics has not been completed (No), the process returns to Step S22, and the temperature information of the semiconductor chip 10 is obtained.

In Step S24 of FIG. 10, in the case where the contact member 24 is in contact with the semiconductor chip 10 (Yes), the state is maintained as it is. Namely, in the case where the measured temperature Tc of the semiconductor chip 10 is higher than the set temperature Ts and the contact member 24 is already in contact with the semiconductor chip 10, the state is maintained as it is. Then, the state is maintained until the temperature of the semiconductor chip 10 is decreased.

Then, as shown in Step S26, in the case where it is determined whether the inspection of the electric characteristics has been completed and the inspection has been completed (Yes), the process is terminated. In the case where the inspection has not been completed (No), the process returns to Step S22.

In the case where the measured temperature Tc is lower than the set temperature Ts (Tc<Ts) in Step S23 of FIG. 10, it is determined whether the contact member 24 is in contact with the semiconductor chip 10 as shown in Step S27 of FIG. 10. In the case where the contact member 24 is in contact with the semiconductor chip 10 (Yes), the contact member 24 is allowed to be separated from the upper surface 10a of the semiconductor chip 10 as shown in Step S28 of FIG. 10.

Then, as shown in Step S26, in the case where it is determined whether the inspection of the electric characteristics has been completed and the inspection has been completed (Yes), the process is terminated. In the case where the inspection has not been completed (No), the process returns to Step S22.

In Step S27, in the case where the contact member 24 is not in contact with the semiconductor chip 10 (No), the state is maintained as it is. Namely, in the case where the measured temperature Tc of the semiconductor chip 10 is lower than the set temperature Ts and the contact member 24 is already separated from the semiconductor chip 10, the state is maintained as it is. Then, the state is maintained until the temperature of the semiconductor chip 10 rises.

Then, as shown in Step S26, in the case where it is determined whether the inspection of the electric characteristics has been completed and the inspection has been completed (Yes), the process is terminated. In the case where the inspection has not been completed (No), the process returns to Step S22.

In the case where the measured temperature Tc is equal to the set temperature Ts (Tc=Ts) in Step S23 of FIG. 10, it is determined whether the inspection of the electric characteristics has been completed as shown in Step S26 of FIG. 10. In the case where the inspection has been completed (Yes), the process is terminated. In the case where the inspection has not been completed (No), the process returns to Step S22.

As described above, the control unit 28 moves the contact member 24 absorbing the heat of the semiconductor chip 10 so as to be brought into contact with or to be separated from the upper surface 10a of the semiconductor chip 10 on the basis of the temperature information extracted from the temperature sensor 12 until the inspection of the electric characteristics of the semiconductor chip 10 in Step S21 of FIG. 10 is completed. Then, after the inspection of the electric characteristics of the semiconductor chip 10 is completed, the wafer inspecting process is terminated.

As described above, in the semiconductor manufacturing method of the embodiment, the temperature information is obtained from the temperature sensor 12 formed in the semiconductor chip 10. Therefore, the temperature of the semiconductor chip 10 in the wafer inspecting process can be accurately measured. Further, the temperature of the semiconductor chip 10 is controlled by allowing the contact member 24 to be directly brought into with the semiconductor chip 10. Therefore, the temperature of the semiconductor chip 10 can be accurately controlled by suppressing unevenness in cooling such as cooling by cooling air.

After the wafer inspecting process of inspecting the semiconductor chip, the test probes 23d are separated from the test pads 11d. Further, after the process of obtaining the temperature information of the semiconductor chip 10, the temperature extraction probe 23e is separated from the temperature extraction pad 11e.

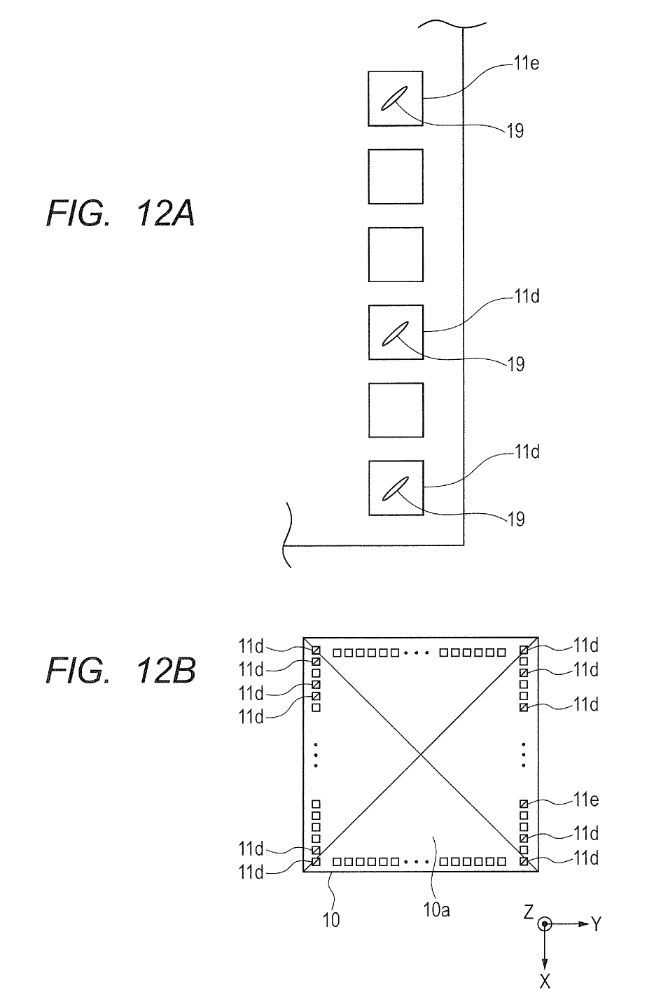

FIG. 12A is a plan view for exemplifying the pads 11 after the wafer inspecting process in the semiconductor manufacturing method according to the first embodiment, and FIG. 12B is a plan view for exemplifying the upper surface 10a of the semiconductor chip 10 after the wafer inspecting process. As shown in FIG. 12A, probe marks 19 are formed on the pads 11d and 11e which are located on the upper surface 10a of the semiconductor chip 10 and with which the probes have been brought into contact. Each probe mark 19 is in, for example, a groove shape. It should be noted that each probe mark 19 is not limited to a groove shape. Each probe mark 19 may be in a recessed shape or a plurality of linear shapes depending on the shape of the tip of each probe.

As shown in FIG. 12B, when the upper surface 10a of the semiconductor chip 10 is viewed from the upper direction, the probe marks 19 are formed on the test pads 11d which are provided on the left side of the upper surface 10a and with which the test probes 23d have been brought into contact. Similarly, the probe marks 19 are formed on the test pads 11d which are provided on the right side of the upper surface 10a and with which the test probes 23d have been brought into contact. Further, the probe mark 19 is also formed on the temperature extraction pad 11e.

Next, as shown in Step S13 of FIG. 4, an assembling process is performed. First, the wafer 30 including the semiconductor chips 10 is diced. Accordingly, the semiconductor chips 10 in the wafer state are separated from each other to be individual semiconductor chips 10. Next, the semiconductor chips 10 individualized by dicing are packaged.

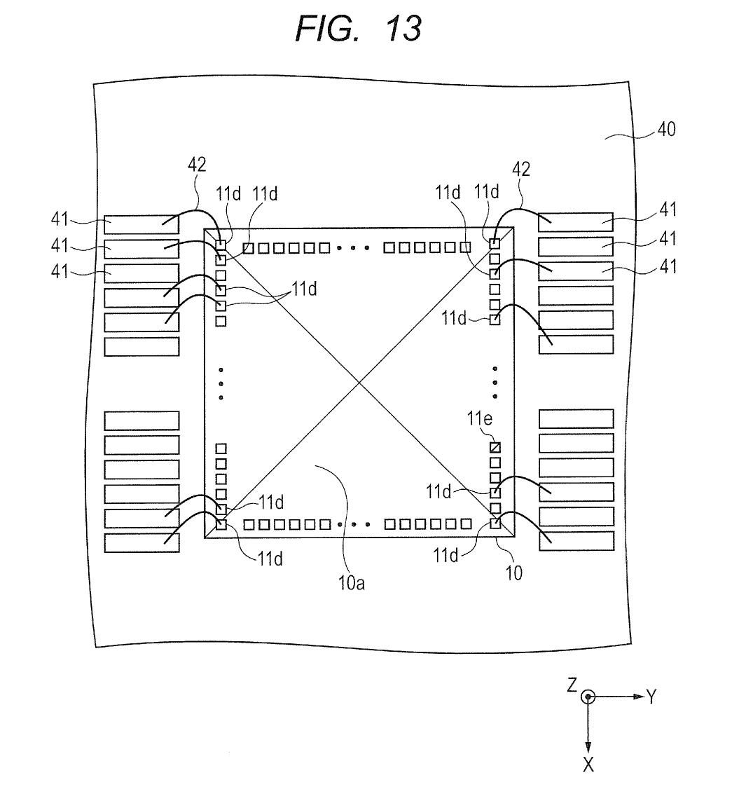

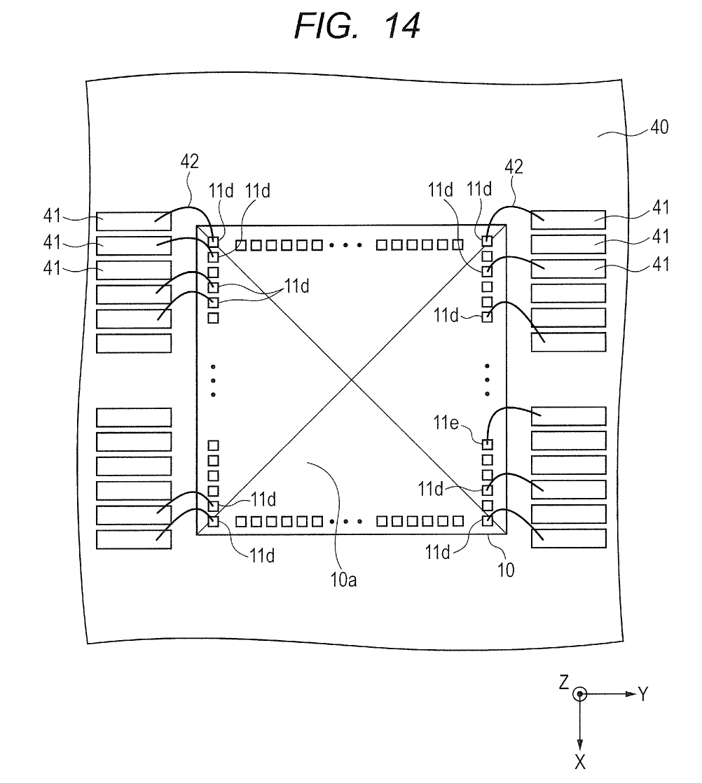

FIG. 13 and FIG. 14 are plan views each exemplifying the packaged semiconductor device in the semiconductor manufacturing method according to the first embodiment. As shown in FIG. 13 and FIG. 14, when packaging, for example, the semiconductor chip 10 is arranged on a support 40 such as a printed board. Then, leads 41 on the support 40 are bonded to the pads 11d and 11e of the semiconductor chip 10. The bonding is, for example, wire bonding using wires 42. Thereafter, the bonded parts are sealed with resin or the like.

The test pads 11d with which the test probes 23d are in contact are wire-bonded and sealed. It should be noted that the test pads 11d need not be wire-bonded. As shown in FIG. 13, the temperature extraction pad 11e with which the temperature extraction probe 23e is in contact is sealed without being wire-bonded. It should be noted that as shown in FIG. 14, when packaging, both the test pads 11d and the temperature extraction pad 11e may be wire-bonded and sealed. Pads other than the test pads 11d and the temperature extraction pad 11e may be also wire-bonded or need not be wire-bonded.

In the case where the temperature extraction pad 11e is used only for temperature extraction, the temperature extraction pad 11e is not wire-bonded in the assembling process. In this case, the probe mark 19 formed by contact with the temperature extraction probe 23e is formed on the temperature extraction pad 11e.

On the other hand, in the case where the temperature extraction pad 11e is used as a terminal after assembly, the temperature extraction pad 11e is wire-bonded in the assembling process. In this case, although the probe mark 19 formed by contact with the temperature extraction probe 23e is formed on the temperature extraction pad 11e, the probe mark 19 is filled with a metal material such as the wire 42 in some cases.

After packaging, a semiconductor device having the semiconductor chip 10 is manufactured through appropriate necessary processes.

Next, effects of the embodiment will be described. The probe card 20 of the embodiment allows the contact member 24 to be brought into contact with and to be separated from the semiconductor chip 10 on the basis of the temperature information from the temperature sensor 12 provided in the semiconductor chip 10. Accordingly, the temperature of the semiconductor chip 10 in the wafer inspecting process can be accurately controlled.

The contact member 24 of the probe card 20 is in direct contact with the semiconductor chip 10. Thus, the heat of the semiconductor chip 10 can be directly absorbed, and the cooling efficiency of the semiconductor chip 10 can be improved. It is possible to suppress unevenness in cooling that has been a problem in the related art when blowing cooling air. Further, the cooling efficiency can be further improved by the contact member 24 containing a material having high heat conductivity. In addition, the contact member 24 is coupled to the heat radiation member 26 via the heat transfer member 25. Since the heat received by the contact member 24 can be radiated by the heat radiation member 26, the cooling efficiency of the semiconductor chip 10 can be improved.

Further, the probe card 20 is arranged so as to face the wafer surface 30a of the wafer 30 in which the semiconductor chips 10 are formed. Thus, since the semiconductor chips 10 to be inspected can be inspected at once, the inspection time can be shortened, and the inspection cost can be suppressed.

The temperature sensor 12 is provided in the semiconductor chip 10. Accordingly, the temperature of the semiconductor chip 10 can be directly measured. The temperature sensor 12 is formed in at least one of the flash memory, the SRAM, the CPU, and the analog IP of the semiconductor chip 10. Accordingly, the temperature of each member of the semiconductor chip 10 can be accurately measured. Further, the wafer surface 30a can be effectively used by forming the temperature sensor 12 in the scribe line 31. In the case where the temperature does not fluctuate in the semiconductor chip 10, the temperature sensors 12 are formed on a reticle basis. Accordingly, it is possible to form the temperature sensors 12 with the minimum number and to reduce the manufacturing cost.

Further, the temperature sensor 12 includes a semiconductor, and outputs the temperature information on the basis of the relation between the temperature and resistance in the semiconductor. Thus, the temperature of the semiconductor chip 10 can be measured more accurately. The temperature distribution in the semiconductor chip 10 can be measured by providing the temperature sensors 12 at the central portion and the peripheral portion of the upper surface 10a of the semiconductor chip 10. With such arrangement of the temperature sensors 12, the temperature of the semiconductor chip 10 to be inspected can be accurately controlled.

### First Modified Example

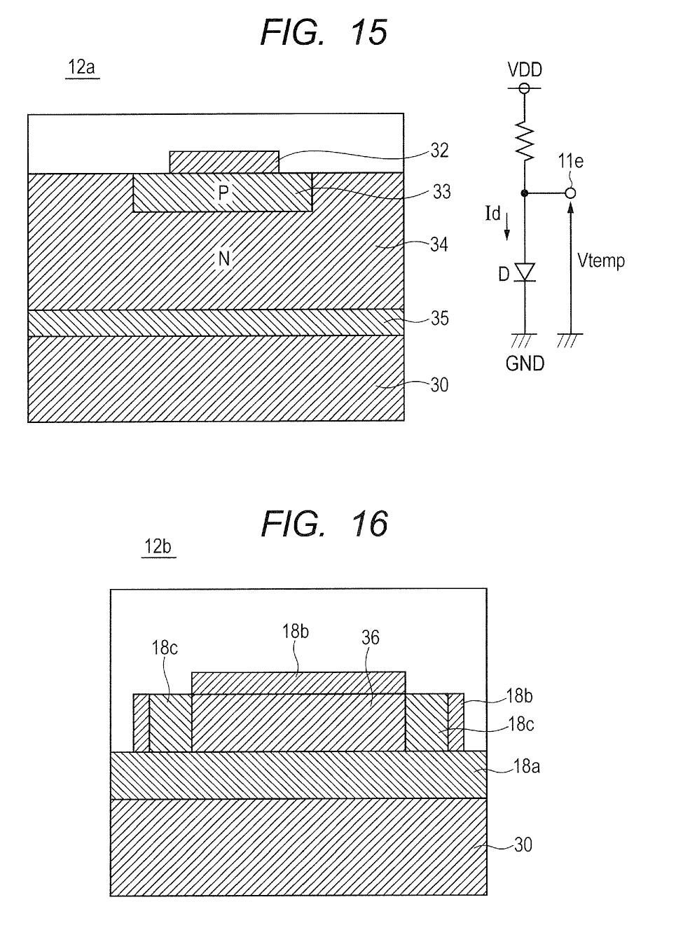

Next, a first modified example of the first embodiment will be described. The modified example is an example in which the structure of the temperature sensor 12 is modified. FIG. 15 is a cross-sectional view for exemplifying a structure of a temperature sensor 12a according to the first modified example of the first embodiment. Electronic circuit symbols showing the structure of the temperature sensor 12a are also shown. As shown in FIG. 15, the temperature sensor 12a of the modified example includes, for example, an anode 32, a P-type region 33, an N-type region 34, and a cathode 35. The temperature sensor 12a has the structure of a diode D. The temperature sensor 12a outputs changes in the current Id and the voltage Vtemp of the diode D as temperature information.

For example, an electrode material is deposited on the wafer 30 to form the cathode 35. Then, a semiconductor film containing N-type impurities is deposited on the cathode 35 to form the N-type region 34. Further, the P-type region 33 containing P-type impurities is formed on the N-type region 34, and an electrode material is further deposited on the P-type region 33 to form the anode 32. The cathode 35 is coupled to a ground terminal GND (not shown) of the wafer 30 via a wiring. The anode 32 is coupled to a power supply VDD via a resistor (not shown), and is coupled to the temperature extraction pad 11e. As described above, the temperature sensor 12a is formed. In the case where the diode D is used as the temperature sensor 12a, for example, the profile shown by the semiconductor in FIG. 9 is obtained. It should be noted that the profile of the temperature sensor 12a using the diode D is not limited to that shown in FIG. 9.

By forming the temperature sensor 12a of the modified example, the temperature sensor 12a can be used not only for temperature measurement in the wafer inspecting process but also as a part of a diode of a semiconductor device circuit, thereby reducing the manufacturing cost. Since the other effects are similar to those of the first embodiment, the explanation thereof is omitted.

### Second Modified Example

Next, a second modified example of the first embodiment will be described. FIG. 16 is a cross-sectional view for exemplifying a structure of a temperature sensor 12b according to the second modified example of the first embodiment. As shown in FIG. 16, the temperature sensor 12b of the modified example is formed using the metal member 36 containing metal. In addition, the temperature sensor 12b has the profile shown by the metal in FIG. 9.

For example, the insulating film 18a is formed on the wafer 30, and the metal member 36 containing metal is formed on the insulating film 18a. Then, the metal member 36 is patterned, and both ends of the metal member 36 are coupled to the temperature extraction pad 11e via a wiring 18c formed in the insulating film 18b. As described above, the temperature sensor 12b is formed so as to output temperature information on the basis of the relation between the temperature and resistance in the metal. As the metal member 36, aluminum, titanium, tungsten, nickel, an alloy of nickel and chromium, an alloy of nickel and tungsten, or a ruthenium oxide film (RuO₂) used in the wafer processing process (Step S11) can be used. In addition, silicon carbide (SiC) can be also used for the metal member 36.

By forming the temperature sensor 12b of the modified example, the temperature sensor 12b can be used not only for temperature extraction but also as a part of a resistor of a semiconductor device circuit, thereby reducing the manufacturing cost. Since the other effects are similar to those of the first embodiment, the explanation thereof is omitted.

### Third Modified Example

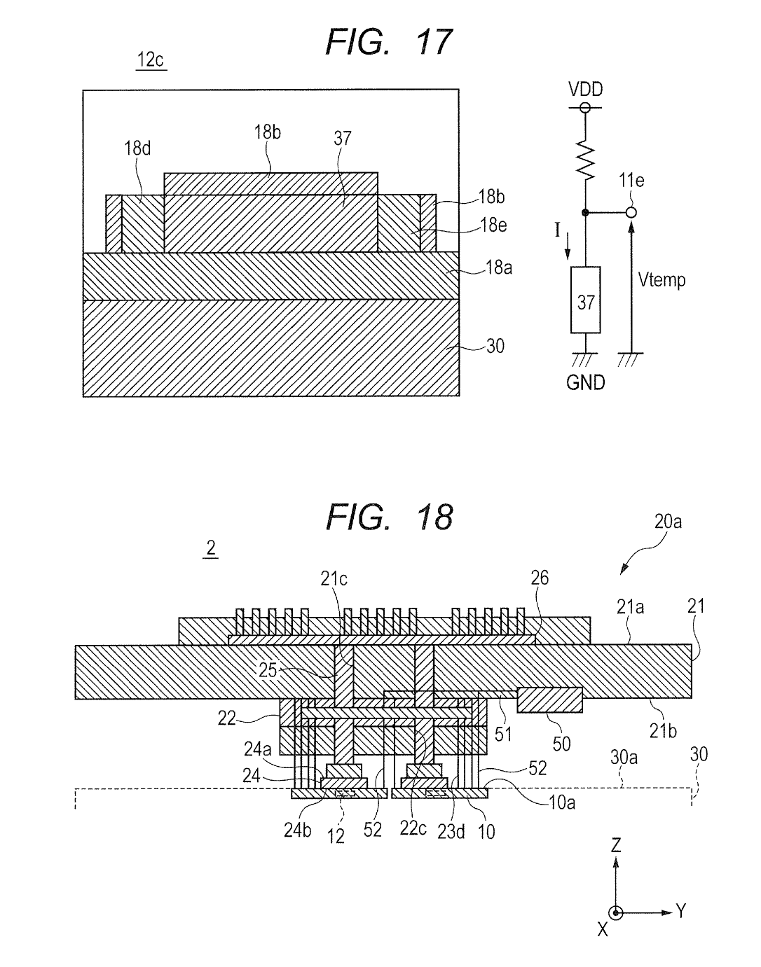

Next, a third modified example of the first embodiment will be described. FIG. 17 is a cross-sectional view for exemplifying a structure of a temperature sensor 12c according to the third modified example of the first embodiment. As shown in FIG. 17, the temperature sensor 12c of the modified example includes a thermistor 37 as a material.

The thermistor 37 uses an NTC (Negative Temperature Coefficient) thermistor whose electric resistance decreases as the temperature rises, or a PTC (Positive Temperature Coefficient) thermistor whose electric resistance increases as the temperature rises depending on a material to be contained.

For example, the insulating film 18a is formed on the wafer 30, and the thermistor 37 is formed on the insulating film 18a. One end of the thermistor 37 is coupled to the ground terminal GND (not shown) of the wafer 30 via a wiring 18d formed in the insulating film 18b. The other end of the thermistor 37 is coupled to the power supply VDD via a resistor (not shown), and is coupled to the temperature extraction pad 11e via a wiring 18e. As described above, the temperature sensor 12c is formed so as to output temperature information on the basis of the relation between the temperature and resistance in the thermistor 37.

By forming the temperature sensor 12c of the modified example, the temperature sensor 12c can be used not only for temperature extraction but also as a part of the thermistor 37 of a semiconductor device circuit, thereby reducing the manufacturing cost. Since the other effects are similar to those of the first embodiment, the explanation thereof is omitted.

### Second Embodiment

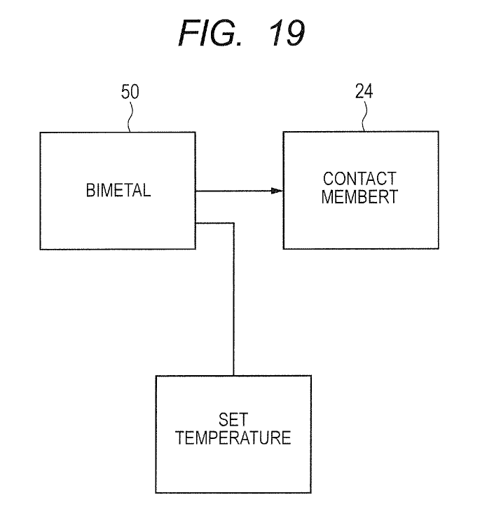

Next, a second embodiment will be described. A probe card 20a of a semiconductor manufacturing device 2 according to the second embodiment uses a bimetal 50 as a mechanism for allowing the contact member 24 to be brought into contact with and to be separated from the upper surface 10a of the semiconductor chip 10. FIG. 18 is a cross-sectional view for exemplifying a configuration of the semiconductor manufacturing device 2 according to the second embodiment. FIG. 19 is a block diagram for exemplifying a method of controlling the contact member 24 using the bimetal 50 according to the second embodiment. As shown in FIG. 18, the probe card 20a has the bimetal 50, a lead wire 51, and heat conduction probes 52.

The bimetal 50 is formed by bonding a plurality of metal plates having different thermal expansion coefficients to each other. Therefore, the metal plates expand with different thermal expansion coefficients according to changes in temperature. Accordingly, the bending direction of the bimetal 50 changes depending on the temperature. In the embodiment, the movement of the contact member 24 is controlled by utilizing such nature of the bimetal 50.

The bimetal 50 is provided, for example, on the lower surface 21b of the main substrate 21. The bimetal 50 is coupled to the heat transfer member 25. Therefore, the heat transfer member 25 can be moved downward or upward by the deformation of the bimetal 50. Accordingly, the contact member 24 can be brought into contact with and to be separated from the upper surface 10a of the semiconductor chip 10.

The deformation of the bimetal 50 is adjusted in advance so that the heat transfer member 25 is moved downward and the contact member 24 is brought into contact with the upper surface 10a of the semiconductor chip 10 when the bimetal 50 becomes equal to or higher than the set temperature in the wafer inspecting process.

The lead wire 51 is a linear member having high heat conductivity, and is, for example, a metal wire. One end of the lead wire 51 is coupled to the bimetal 50. The other end of the lead wire 51 is coupled to one end of the heat conduction probe 52. The lead wire 51 has a function of transmitting the heat conducted to the heat conduction probe 52 to the bimetal 50.

The heat conduction probe 52 is a thin needle-like member having high heat conductivity, and is a probe that obtains the heat of the semiconductor chip 10. One end of the heat conduction probe 52 is fixed to the relay substrate 22. Further, the other end of the lead wire 51 is coupled to one end of the heat conduction probe. The other end of the heat conduction probe is a tip, and can be brought into contact with the temperature extraction pad 11e of the semiconductor chip 10.

In the wafer inspecting process, the heat conduction probe 52 is brought into contact with the temperature extraction pad 11e of the semiconductor chip 10. Accordingly, the heat conduction probe 52 obtains heat from the semiconductor chip 10. The heat obtained by the heat conduction probe 52 is transmitted to the bimetal 50 via the lead wire 51.

As shown in FIG. 19, when the temperature of the bimetal 50 becomes higher than the set temperature as a result of receiving the heat from the lead wire 51, the bimetal 50 is deformed, and allows the contact member 24 to be brought into contact with the upper surface 10a of the semiconductor chip 10. On the other hand, when the temperature of the semiconductor chip 10 is decreased as a result of allowing the contact member 24 to be brought into contact with the semiconductor chip 10, the heat received by the bimetal 50 via the lead wire 51 is decreased. Accordingly, the temperature of the bimetal 50 becomes lower than the set temperature. As a result, the bimetal 50 is deformed so as to separate the contact member 24 from the upper surface 10a of the semiconductor chip 10. In this way, the bimetal 50 allows the contact member 24 to be brought into contact with and to be separated from the upper surface 10a of the semiconductor chip 10 on the basis of the set temperature as a reference.

According to the probe card 20a of the second embodiment, it is possible to control the movement of the contact member 24 using the bimetal 50. Therefore, the temperature of the semiconductor chip 10 can be accurately controlled. Further, the driving unit 27 and the control unit 28 can be omitted. Therefore, the manufacturing cost can be reduced.

The matters shown below also belong to the technical scope of the invention.

### (Supplementary Note 1)

A semiconductor manufacturing device including a probe card arranged to face a semiconductor chip to be measured,

wherein the probe card has:

a test probe that obtains the electric characteristics of the semiconductor chip by being brought into contact with a test pad provided over the upper surface of the semiconductor chip;

a heat conduction probe that obtains the heat of the semiconductor chip by being brought into contact with a temperature extraction pad provided over the upper surface;

a contact member that is brought into contact with the upper surface of the semiconductor chip to absorb the heat of the semiconductor chip; and

a bimetal that moves the contact member so as to allow the contact member to be brought into contact with or to be separated from the upper surface.

### (Supplementary Note 2)

A semiconductor manufacturing method including the steps of:

obtaining the electric characteristics of a semiconductor chip by allowing a test probe to be brought into contact with a test pad provided over the upper surface of the semiconductor chip to be measured;

obtaining the heat of the semiconductor chip by allowing a heat conduction probe to be brought into contact with a temperature extraction pad provided over an upper surface; and

moving a contact member absorbing the heat of the semiconductor chip to be brought into contact with or to be separated from the upper surface to a bimetal by using the obtained heat.

The invention achieved by the inventors has been concretely described above on the basis of the embodiments. However, it is obvious that the present invention is not limited to the above-described embodiments, and can be variously changed without departing from the gist thereof.

What is claimed is:

1. A semiconductor manufacturing device comprising a probe card arranged to face a semiconductor chip to be measured,
wherein the probe card has:
a test probe that obtains the electric characteristics of the semiconductor chip by being brought into contact with a test pad provided over the upper surface of the semiconductor chip;
a temperature extraction probe that extracts temperature information of the semiconductor chip by being brought into contact with a temperature extraction pad that is coupled to a temperature sensor provided in the semiconductor chip and is provided over the upper surface;
a contact member that is brought into contact with the upper surface of the semiconductor chip to absorb the heat of the semiconductor chip;
a driving unit that moves the contact member so as to allow the contact member to be brought into contact with or to be separated from the upper surface; and
a control unit that controls the driving of the driving unit on the basis of the temperature information.

2. The semiconductor manufacturing device according to claim 1,
wherein the probe card further includes:
a heat radiation member that is provided on the side opposite to the side where the semiconductor chip is arranged and radiates the heat absorbed by the contact member; and
a heat transfer member that couples the contact member and the heat radiation member to each other and moves the heat absorbed by the contact member to the heat radiation member, and
wherein the driving unit moves the contact member via the heat transfer member.

3. The semiconductor manufacturing device according to claim 1,
wherein the probe card is arranged so as to face the wafer surface of a wafer where the semiconductor chips are formed to simultaneously inspect the semiconductor chips formed in the wafer.

4. A semiconductor manufacturing method comprising the steps of:
obtaining the electric characteristics of a semiconductor chip by allowing a test probe to be brought into contact with a test pad provided over the upper surface of the semiconductor chip to be measured;
obtaining temperature information of the semiconductor chip by allowing a temperature extraction probe to be brought into contact with a temperature extraction pad that is coupled to a temperature sensor provided in the semiconductor chip and is provided over the upper surface; and
moving a contact member absorbing the heat of the semiconductor chip to be brought into contact with or to be separated from the upper surface on the basis of the temperature information.

5. The semiconductor manufacturing method according to claim 4, further comprising the steps of:
before the step of obtaining the electric characteristics of the semiconductor chip, forming the semiconductor chips in the wafer;
after the step of obtaining the electric characteristics of the semiconductor chip, separating the test probe from the test pad;
after the step of obtaining the temperature information of the semiconductor chip, separating the temperature extraction probe from the temperature extraction pad;
after the steps of separating the test probe and the temperature extraction probe, dicing the wafer; and
packaging the semiconductor chips individually diced, wherein in the step of packaging, the test pad is wire-bonded and sealed, and the temperature extraction pad is sealed without being wire-bonded.

6. The semiconductor manufacturing method according to claim 4, further comprising the steps of:
before the step of obtaining the electric characteristics of the semiconductor chip, forming the semiconductor chips in the wafer;
after the step of obtaining the electric characteristics of the semiconductor chip, separating the test probe from the test pad;
after the step of obtaining the temperature information of the semiconductor chip, separating the temperature extraction probe from the temperature extraction pad;
after the steps of separating the test probe and the temperature extraction probe, dicing the wafer; and
packaging the semiconductor chips individually diced,
wherein in the step of packaging, the test pad and the temperature extraction pad are wire-bonded and sealed.

7. The semiconductor manufacturing method according to claim 5,
wherein in the step of forming the semiconductor chip, the temperature sensor includes a semiconductor, and the semiconductor chip is formed to output the temperature information on the basis of a relation between a temperature and resistance in the semiconductor.

8. The semiconductor manufacturing method according to claim 5,
wherein in the step of forming the semiconductor chip, the temperature sensor includes metal, and the semiconductor chip is formed to output the temperature information on the basis of a relation between a temperature and resistance in the metal.

9. The semiconductor manufacturing method according to claim 5,
wherein in the step of forming the semiconductor chip, the temperature sensor includes a thermistor, and the semiconductor chip is formed to output the temperature information on the basis of a relation between a temperature and resistance in the thermistor.

10. The semiconductor manufacturing method according to claim 5,
wherein in the step of forming the semiconductor chip, the temperature sensor is formed in at least one of a flash memory, an SRAM, a CPU, and an analog IP of the semiconductor chip.

11. The semiconductor manufacturing method according to claim 5,
wherein in the step of forming the semiconductor chip, the temperature sensor is formed in a scribe line between the semiconductor chips.

12. The semiconductor manufacturing method according to claim 5,
wherein in the step of forming the semiconductor chip, the temperature sensor is formed for each region formed on a reticle basis in the wafer including the semiconductor chip.

13. A semiconductor device having a semiconductor chip,
wherein the semiconductor chip includes:
a test pad with which a test probe for obtaining the electric characteristics of the semiconductor chip is brought into contact;
a temperature sensor that outputs temperature information of the semiconductor chip; and
a temperature extraction pad which is coupled to the temperature sensor and with which a temperature extraction probe for extracting the temperature information is brought into contact,
wherein the test pad and the temperature extraction pad are provided over the upper surface of the semiconductor chip, and
wherein a contact member for absorbing heat can be brought into contact with the upper surface of the semiconductor chip.

14. The semiconductor device according to claim 13,
wherein the test pad is wire-bonded and sealed, and
wherein the temperature extraction pad is sealed without the wire bonding.

15. The semiconductor device according to claim 14,
wherein a probe mark formed by contact with the temperature extraction probe is formed on the temperature extraction pad.

16. The semiconductor device according to claim 13,
wherein the test pad and the temperature extraction pad are wire-bonded and sealed.

17. The semiconductor device according to claim 13,
wherein the temperature sensor includes a semiconductor, and outputs the temperature information on the basis of a relation between a temperature and resistance in the semiconductor.

18. The semiconductor device according to claim 13,
wherein the temperature sensor includes metal, and outputs the temperature information on the basis of a relation between a temperature and resistance in the metal.

19. The semiconductor device according to claim 13,
wherein the temperature sensor includes a thermistor, and outputs the temperature information on the basis of a relation between a temperature and resistance in the thermistor.

20. The semiconductor device according to claim 13,
wherein the semiconductor chip includes at least one of a flash memory, an SRAM, a CPU, and an analog IP, and
wherein the temperature sensor is formed in the one.
